(19) United States
(12) Patent Application Publication
(10) Pub. No.: US 2025/0008717 A1
(43) Pub. Date: Jan. 2, 2025

(54) COMPONENT MOUNTING MACHINE AND METHOD FOR MANUFACTURING SUBSTRATE

(71) Applicant: FUJI CORPORATION, Chiryu (JP)

(72) Inventors: Kenji SUZUKI, Nagoya-shi (JP); Hideya KURODA, Toyota-shi (JP); Kenji NAKAI, Anjo-shi (JP); Masayo GOTO, Toyoake-shi (JP)

(73) Assignee: FUJI CORPORATION, Chiryu (JP)

(21) Appl. No.: 18/703,604

(22) PCT Filed: Nov. 11, 2021
(86) PCT No.: PCT/JP2021/041536

§ 371 Date: Apr. 22, 2024

(51) Int. Cl. H05K 13/04

(52) U.S. Cl. CPC H05K 13/0406; H05K 13/0409; H05K 13/0419

(57) ABSTRACT

There is a component mounter of the present disclosure for collecting a component accommodated in a tray supplied from a tray unit and mounting the component on a board, including: a head configured to hold multiple suction nozzles capable of collecting the component; a first nozzle lifting and lowering device configured to vertically move a suction nozzle at a predetermined position of the head with respect to the head; a second nozzle lifting and lowering device configured to vertically move a suction nozzle at a position different from the predetermined position of the head with respect to the head; a head lifting and lowering device configured to vertically move the head; and a head moving device configured to move the head in a horizontal direction together with the head lifting and lowering device.

### TECHNICAL FIELD

The present description discloses a component mounter and a method for manufacturing a board.

### BACKGROUND ART

Conventionally, a component mounter is known in which a component accommodated in a tray is picked up by a suction nozzle provided in a pickup head and mounted on a board by using the suction nozzle. For example, in Patent Literatures 1 and 2, there is disclosed a component mounter including a head that holds a suction nozzle, a device that lifts and lowers the suction nozzle, and a device that horizontally moves the head. In such a component mounter, a component accommodated in a tray is picked up by the suction nozzle as follows. That is, first, a pickup head is moved onto a desired component. Next, the suction nozzle is moved downward to the pickup head. Then, a negative pressure is applied to a tip of the suction nozzle to pick up the component.

### PATENT LITERATURE

Patent Literature 1: JP-A-2014-167955
Patent Literature 2: JP-A-2019-029499

### BRIEF SUMMARY

### Technical Problem

However, in such a component mounter, since it takes time to lift and lower the nozzle, overall production efficiency deteriorates, and there is room for improvement.

A main object of the present disclosure is to shorten a time required for collecting a component accommodated in a tray when collecting the component by using a collecting member.

### Solution to Problem

According to the present disclosure, there is provided a first component mounter for collecting a component accommodated in a tray supplied from a tray unit and mounting the component on a board, including: a head configured to hold multiple collecting members capable of collecting the component: a first lifting and lowering device configured to vertically move a collecting member at a predetermined position of the head with respect to the head: a second lifting and lowering device configured to vertically move a collecting member at a position different from the predetermined position of the head with respect to the head: a head lifting and lowering device configured to vertically move the head; and a head moving device configured to move the head lifting and lowering device in a horizontal direction together with the head.

Since the component mounter includes the head lifting and lowering device that vertically moves the head, the component accommodated in the tray can be collected in a state where the head is lowered to the vicinity of the component accommodated in the tray by driving of the head lifting and lowering device. Therefore, the amount of vertical movement of the collecting member by the first lifting and lowering device and the second lifting and lowering device can be reduced. Accordingly, when the component accommodated in the tray is collected by using the collecting member, a time required for collecting the component can be shortened.

According to the present disclosure, there is provided a second component mounter for collecting a component accommodated in a tray supplied from a tray unit and mounting the component on a board, including: a head configured to hold multiple collecting members capable of collecting the component: a first lifting and lowering device configured to vertically move a collecting member at a predetermined position of the head with respect to the head: a second lifting and lowering device configured to vertically move a collecting member at a position different from the predetermined position of the head with respect to the head: a head moving device configured to move the head in a horizontal direction; and a control device configured to cause the head moving device, the first lifting and lowering device, and the second lifting and lowering device to collect a component accommodated in a first region by the collecting member that is vertically moved by the first lifting and lowering device, and to collect a component accommodated in a second region different from the first region by the collecting member that is vertically moved by the second lifting and lowering device, among components accommodated in the tray, in which the head does not come into contact with an obstacle in a case where a component in a specific region of the tray is collected by using the collecting member that is vertically moved by the first lifting and lowering device, and comes into contact with the obstacle in a case where the component in the specific region of the tray is collected by using the collecting member that is vertically moved by the second lifting and lowering device, the first region is the specific region, and the second region is a region other than the specific region.

In the second component mounter, the head does not come into contact with an obstacle in a case where a component in a specific region of the tray is collected by using the collecting member that is vertically moved by the first lifting and lowering device, and comes into contact with the obstacle in a case where the component in the specific region of the tray is collected by using the collecting member that is vertically moved by the second lifting and lowering device. In addition, the head moving device, the first lifting and lowering device, and the second lifting and lowering device are controlled such that a component accommodated in a first region is collected by the collecting member that is vertically moved by the first lifting and lowering device, and a component accommodated in a second region different from the first region is collected by the collecting member that is vertically moved by the second lifting and lowering device, among components accommodated in the tray. At this time, the first region is the specific region, and the second region is a region other than the specific region. Therefore, even in a case where the component accommodated in the tray is collected by any collecting member, the head can be prevented from coming into contact with the obstacle.

A method for manufacturing a board according to the present disclosure also achieves the same effect.

### BRIEF DESCRIPTION OF DRAWINGS

FIG. 1 is a diagram illustrating a schematic configuration of component mounting system 1.

FIG. 2 is a diagram schematically illustrating a schematic configuration of component mounter 10.

FIG. 3 is a plan view illustrating a schematic configuration of component mounter 10.

FIG. 4 is a diagram illustrating a schematic configuration of head lifting and lowering device 30.

FIG. 5 is a diagram illustrating a schematic configuration of tray feeder 50.

FIG. 6 is a diagram illustrating a schematic configuration of tape feeder 60 and feeder table 70.

FIG. 7 is a perspective view illustrating feeder table 70 and tray moving device 55.

FIG. 8A is a diagram illustrating a state of movement of head 12.

FIG. 8B is a diagram when FIG. 8A is viewed from above.

FIG. 9A is a diagram illustrating a state of movement of head 12.

FIG. 9B is a diagram when FIG. 9A is viewed from above.

FIG. 10 is a block diagram illustrating an electric connection relationship of component mounting system 1.

FIG. 11 is a flowchart illustrating an example of a component mounting process routine.

FIG. 12 is a diagram of first region R1 and second region R2.

FIG. 13A is a diagram illustrating an operation of head 12 when executing a component mounting process.

FIG. 13B is a diagram illustrating the operation of head 12 when executing the component mounting process.

FIG. 13C is a diagram illustrating the operation of head 12 when executing the component mounting process.

FIG. 13D is a diagram illustrating the operation of head 12 when executing the component mounting process.

FIG. 14 is a diagram illustrating a schematic configuration of rotary head 112.

### DESCRIPTION OF EMBODIMENTS

Preferred embodiments of a component mounter of the present disclosure will be described below with reference to the accompanying drawings.

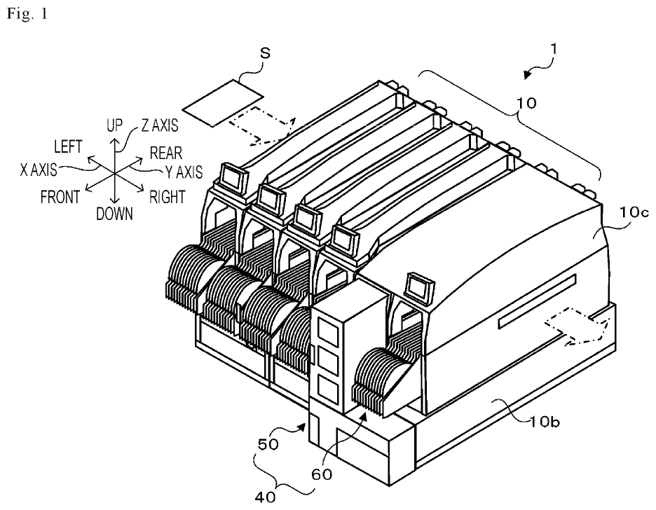

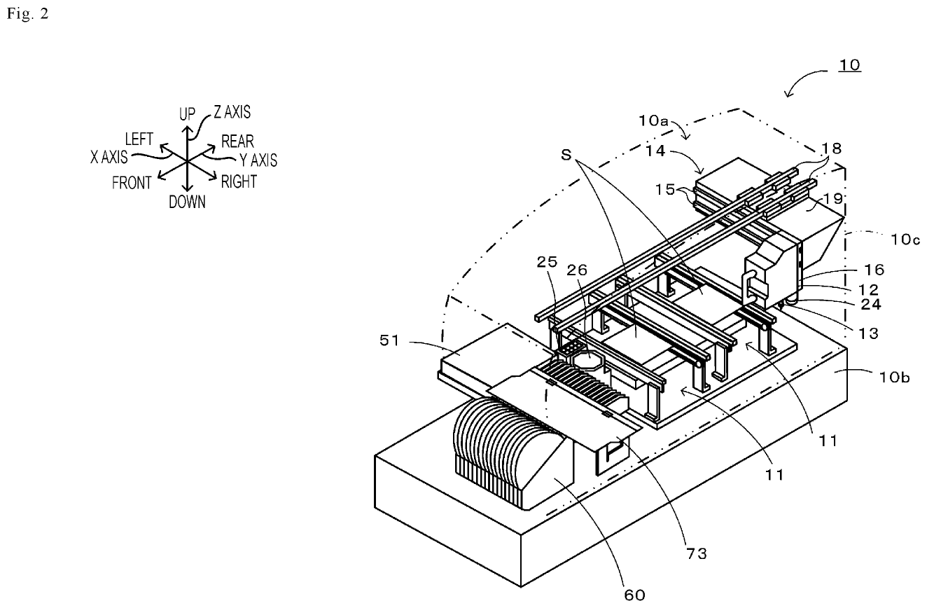

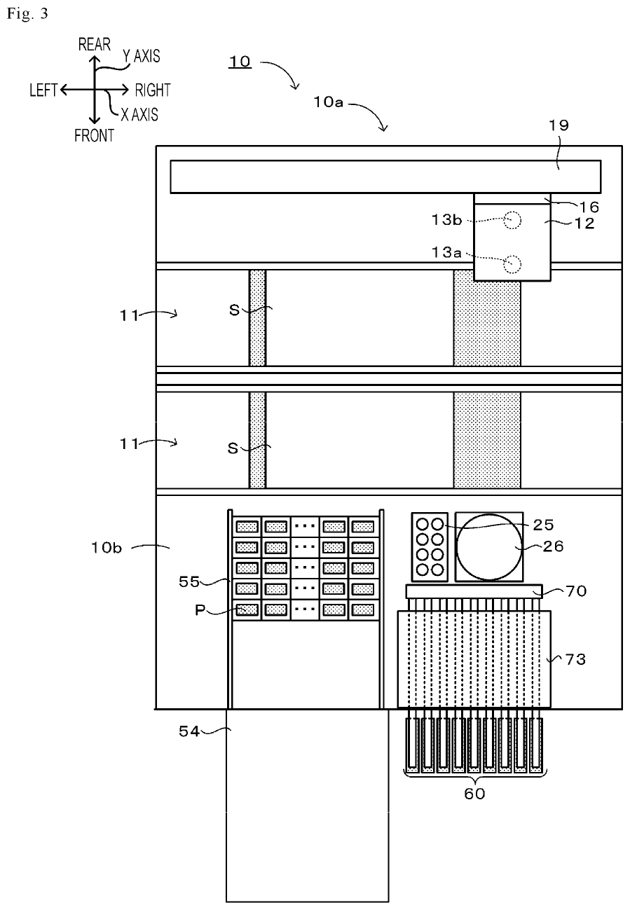

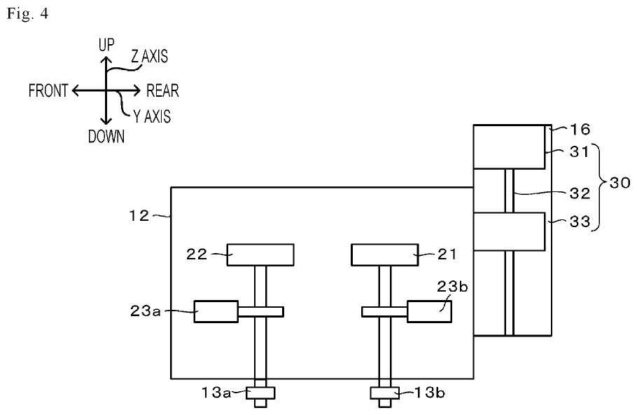

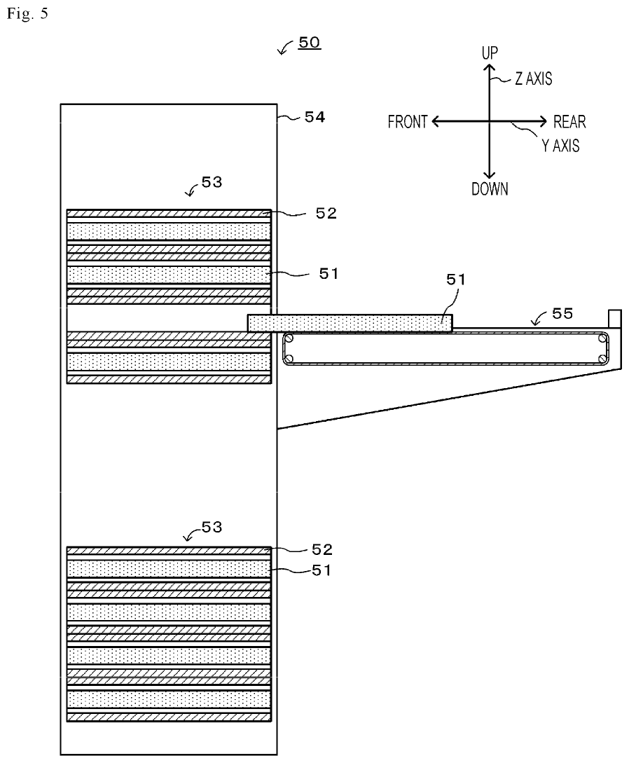

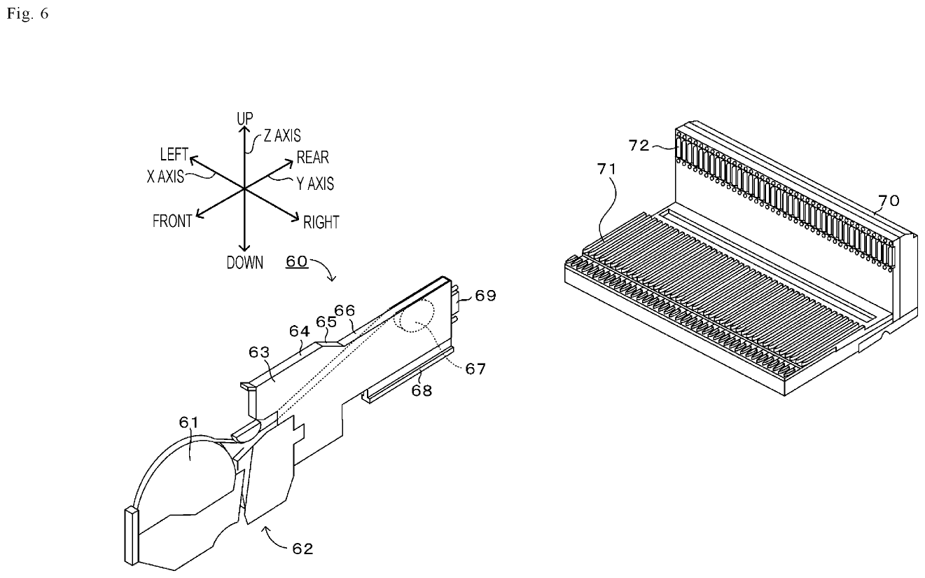

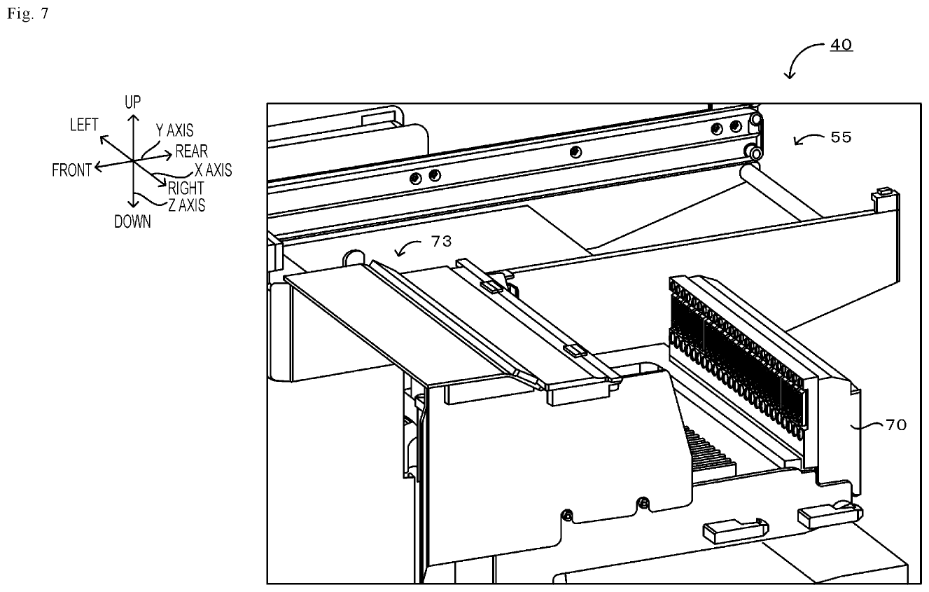

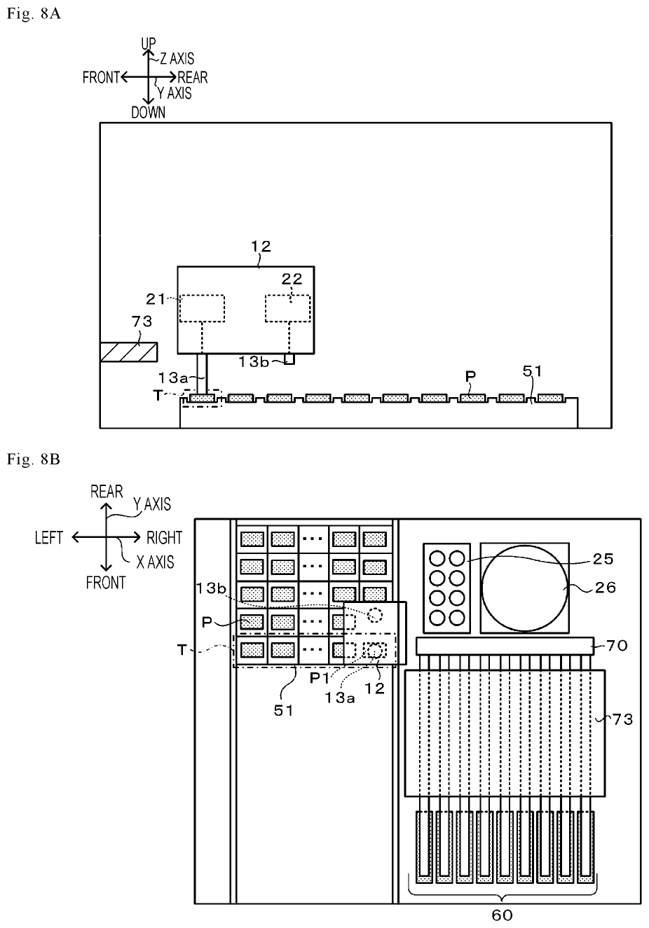

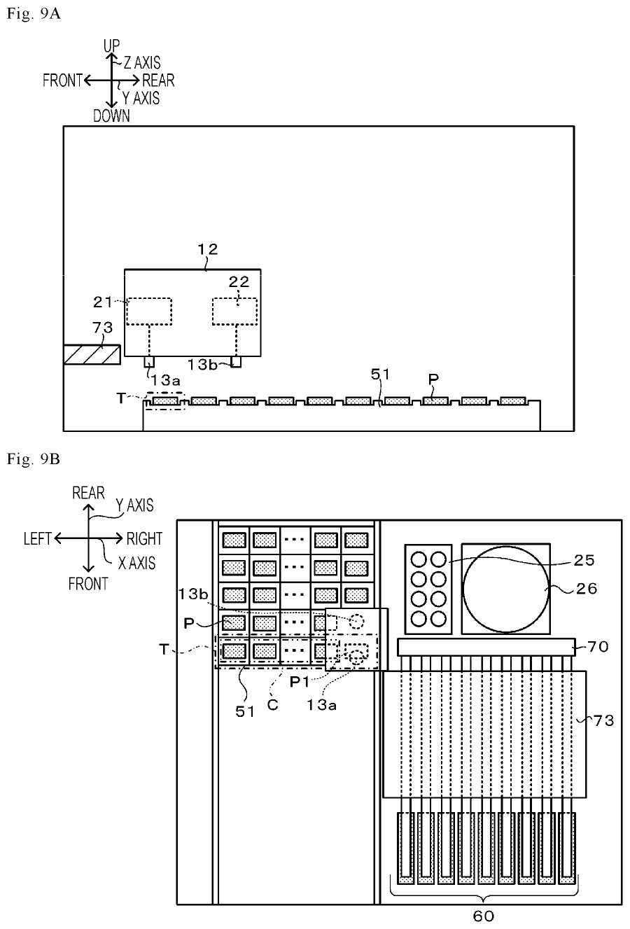

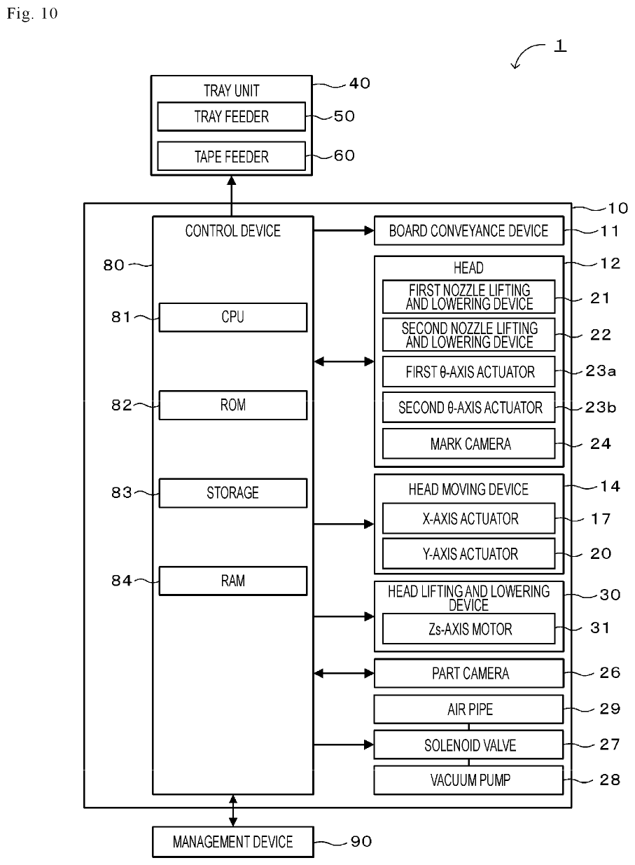

FIG. 1 is a diagram illustrating a schematic configuration of component mounting system 1. FIG. 2 is a diagram schematically illustrating a schematic configuration of component mounter 10. FIG. 3 is a plan view illustrating a schematic configuration of component mounter 10. FIG. 4 is a diagram illustrating head lifting and lowering device 30. FIG. 5 is a diagram illustrating a schematic configuration of tray feeder 50. FIG. 6 is a diagram illustrating a schematic configuration of tape feeder 60 and feeder table 70. FIG. 7 is a perspective view illustrating feeder table 70 and tray moving device 55. FIGS. 8A and 9A are diagrams illustrating a state of vertical movement of head 12. FIGS. 8B and 9B are diagrams when FIGS. 8A and 9A are viewed from above, respectively. FIG. 10 is a block diagram illustrating an electric connection relationship of component mounting system 1. A right-left direction in FIGS. 1 to 3, 6, 7, and 9 is an X-axis direction (a direction perpendicular to the page plane in FIGS. 4 and 5 is the X-axis direction), a front-rear direction in FIGS. 1 to 3, 4, and 5 to 9 is a Y-axis direction, and an up-down direction in FIGS. 1 to 2, 4 to 7, 8A, and 9A is a Z-axis direction (a direction perpendicular to the page plane in FIGS. 3, 8B, and 9B is the Z-axis direction).

As illustrated in FIG. 1, component mounting system 1 includes multiple component mounters 10 arranged along a conveyance direction (X-axis direction) of board S, tray unit 40 that supplies a component to component mounter 10, and management device 90 (see FIG. 10) that manages entire component mounting system 1.

Component mounter 10 picks up (collects) the component supplied from tray unit 40 and mounts the component on board S, and includes base 10b and mounting machine main body 10a provided on base 10b, as illustrated in FIG. 2. An entirety of mounting machine main body 10a is covered with casing 10c. Mounting machine main body 10a includes board conveyance device 11 that conveys board S, head 12 that can hold multiple suction nozzles 13 that pick up components, head lifting and lowering device 30 (see FIG. 4) that vertically moves head 12, head moving device 14 that moves head 12 in a horizontal direction (X-axis direction and Y-axis direction) together with head lifting and lowering device 30, and control device 80 (see FIG. 10). In addition, mounting machine main body 10a includes part camera 26 for capturing an image of a pickup posture of a component picked up by suction nozzle 13, nozzle stocker 25 for stocking multiple types of suction nozzles 13 attachable to head 12, or the like.

Board conveyance device 11 is provided with a pair of conveyor rails arranged at intervals in the Y-axis direction, and conveys board S from the left to the right in FIGS. 1 and 2 (conveyance direction) by driving the pair of conveyor rails. A distance between the pair of conveyor rails in the Y-axis direction can be changed, and board conveyance device 11 can convey boards having different widths in the Y-axis direction.

As illustrated in FIG. 4, head 12 includes two suction nozzles 13 (first suction nozzle 13a and second suction nozzle 13b), first nozzle lifting and lowering device 21 that moves first suction nozzle 13a in the Z-axis (vertical) direction between a lifting position and a lowering position, second nozzle lifting and lowering device 22 that moves second suction nozzle 13b in the Z-axis (vertical) direction between a lifting position and a lowering position, first θ-axis actuator 23a that rotates first suction nozzle 13a about the Z-axis, second θ-axis actuator 23b that rotates second suction nozzle 13b about the Z-axis, and mark camera 24 (see FIG. 2) for imaging board S. First suction nozzle 13a and second suction nozzle 13b are held by head 12 in a state of being spaced apart from each other along the Y-axis direction as illustrated in FIG. 4. Suction ports of first suction nozzle 13a and second suction nozzle 13b selectively communicate with any one of vacuum pump 28 (see FIG. 10) and air pipe 29 (see FIG. 10) via solenoid valve 27 (see FIG. 10). First suction nozzle 13a and second suction nozzle 13b are capable of applying a negative pressure to the suction port to pick up a component by driving solenoid valve 27 such that the suction port communicates with vacuum pump 28, and are capable of applying a positive pressure to the suction port to release the picking up of the component by driving solenoid valve 27 such that the suction port communicates with air pipe 29.

As illustrated in FIG. 4, head lifting and lowering device 30 is provided on X-axis slider 16. Head lifting and lowering device 30 includes Zs-axis motor 31, ball screw 32, and movable body 33. Ball screw 32 is screwed into a ball nut (not illustrated) fixed to movable body 33. Therefore, movable body 33 is lifted and lowered along the vertical direction by rotationally driving ball screw 32 with Zs-axis motor 31. Further, movable body 33 holds head 12. Accordingly, head lifting and lowering device 30 vertically moves head 12 by driving of Zs-axis motor 31 to vertically move movable body 33.

Head moving device 14 includes pair of X-axis guide rails 15. X-axis slider 16. X-axis actuator 17 (see FIG. 10), pair of Y-axis guide rails 18, Y-axis slider 19, and Y-axis actuator 20 (see FIG. 10). Pair of Y-axis guide rails 18 are installed on an upper stage in casing 10c to extend in parallel to each other in the Y-axis direction. Y-axis slider 19 extends to span pair of Y-axis guide rails 18 and is moved in the Y-axis direction along Y-axis guide rails 18 by the driving of Y-axis actuator 20. Pair of X-axis guide rails 15 are installed on a front surface of Y-axis slider 19 to extend in parallel to each other in the X-axis direction. X-axis slider 16 extends to span pair of X-axis guide rails 15 and is moved in the X-axis direction along X-axis guide rails 15 by the driving of X-axis actuator 17. X-axis slider 16 is provided with head lifting and lowering device 30, and head 12 is attached to movable body 33 of head lifting and lowering device 30. Therefore, head moving device 14 moves head 12 in the X-axis direction and the Y-axis direction together with head lifting and lowering device 30 by moving X-axis slider 16 and Y-axis slider 19.

As illustrated in FIG. 10, control device 80 is configured as a microprocessor including CPU 81 as a main component, and includes ROM 82, storage 83 (for example, an HDD or an SSD), and RAM 84, in addition to CPU 81. Control device 80 outputs a control signal to tray unit 40, board conveyance device 11, head 12, head moving device 14, head lifting and lowering device 30, part camera 26, solenoid valve 27, or the like. Control device 80 receives an image signal from mark camera 24 or part camera 26, and receives a control signal from management device 90.

Tray unit 40 is detachably attached to component mounter 10. When attached to component mounter 10, tray unit 40 is electrically connected to component mounter 10. As illustrated in FIG. 1, tray unit 40 includes tray feeder 50 capable of supplying a component to component mounter 10 by tray 51 in which component P is accommodated, and tape feeder 60 aligned and arranged in the right-left direction (X-axis direction) and capable of supplying the component to component mounter 10 by a tape.

As illustrated in FIG. 5, tray feeder 50 includes tray storage device 54 having magazine 52 capable of accommodating multiple trays 51 and holding section 53 for holding magazine 52 to be vertically movable, and tray moving device 55 for taking out desired tray 51 from magazine 52 held by holding section 53. As illustrated in FIG. 5, tray storage device 54 has holding sections 53 in an upper stage and a lower stage. Tray 51 has multiple recessed portions formed in a grid pattern, and component P to be mounted on board S is accommodated in each of the recessed portions.

As illustrated in FIG. 6, tape feeder 60 is set at feeder table 70. As illustrated in FIG. 6, tape feeder 60 includes holding member 62, main body portion 63, rail 68 provided at a lower portion of main body portion 63, and connector 69 provided at a tip portion of main body portion 63. Holding member 62 is a member that holds tape reel 61 around which a carrier tape accommodating a component is wound at predetermined intervals. Main body portion 63 has tape feeding mechanism 67 which draws out the carrier tape from tape reel 61 by driving of a drive motor and feeds the carrier tape to a component supply position. As illustrated in FIG. 6, an upper portion of main body portion 63 has, for example, step surfaces 64 to 66, in which a base end side extends to be inclined upward from a tip end side, to form a hand of tape feeder 60.

Feeder table 70 is disposed at a position adjacent to tray 51 in the X-axis direction in tray unit 40. As illustrated in FIG. 6, feeder table 70 has multiple slots 71 for detachably holding tape feeder 60. Rail 68 of tape feeder 60 is inserted into each of slots 71. Connector 72 corresponding to each of slots 71 is provided on an upright wall provided at a rear end of feeder table 70. Connector 69 of tape feeder 60 is electrically connected to connector 72 of feeder table 70.

As illustrated in FIG. 7, feeder table 70 is provided with cover member 73 that covers step surfaces 64 to 66 of tape feeder 60 when tape feeder 60 is attached. As illustrated in FIGS. 8A and 9A, a height of cover member 73 is higher than a height of tray 51. Therefore, when head 12 picks up component P accommodated in tray 51 in a state where head 12 is lowered by driving of head lifting and lowering device 30, head 12 interferes with cover member 73, in some cases. That is, head 12 does not interfere with cover member 73 in a case where head 12 picks up component P on the rightmost side of specific region T as illustrated in FIGS. 8A and 8B by using first suction nozzle 13a in a state where head 12 is lowered by the driving of head lifting and lowering device 30. Meanwhile, head 12 interferes with cover member 73 in a case where head 12 picks up component P on the rightmost side of specific region T as illustrated in FIGS. 9A and 9B by using second suction nozzle 13b in a state where head 12 is lowered by the driving of head lifting and lowering device 30. In this manner, in a case where component P in specific region T is picked up by using second suction nozzle 13b in a state where head 12 is lowered by the driving of head lifting and lowering device 30, cover member 73 becomes an obstacle in the operation of head 12, in some cases. Whether there is an obstacle in the operation of head 12 is determined in advance based on a size of head 12, a type of tray 51, or the like. Therefore, specific region T is set in advance based on the size of head 12, the type of tray 51, or the like. Specific region T is set as follows, for example. Here, as illustrated in FIGS. 9A and 9B, in a case where component P is picked up by using second suction nozzle 13b in a state where head 12 is lowered by head lifting and lowering device 30, component P at a position at which head 12 and cover member 73 are in contact with each other is referred to as specific component P1. At this time, specific region T is a region including multiple components P aligned with specific component P1 in the X-axis direction as illustrated in FIGS. 8B and 9B. In the present embodiment, some of components P in specific region T include a component with which head 12 does not interfere with cover member 73 even when the component is picked up by second suction nozzle 13b in a state where head 12 is lowered (see portion C in FIG. 9B).

Management device 90 is configured as a microprocessor mainly including CPU, and includes ROM, a storage, and RAM in addition to the CPU. Management device 90 exchanges signals with control device 80 as illustrated in FIG. 10.

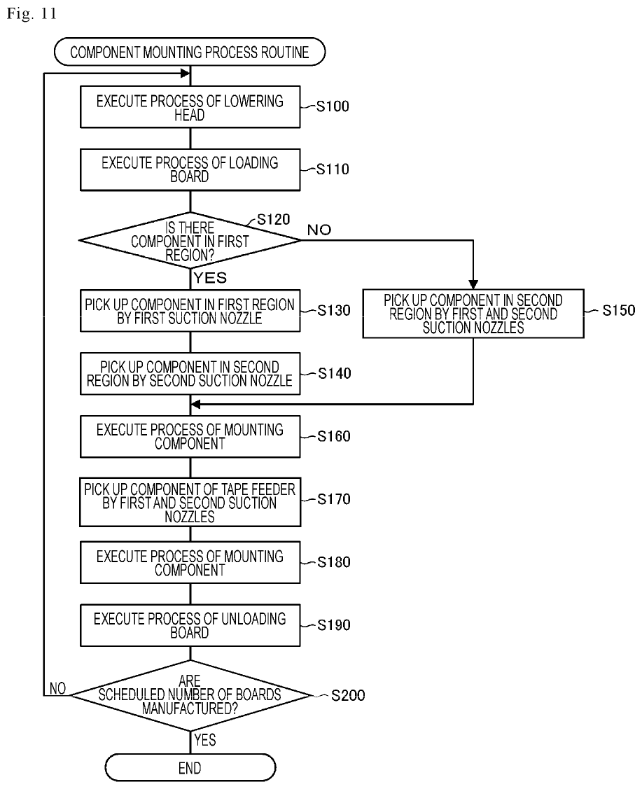

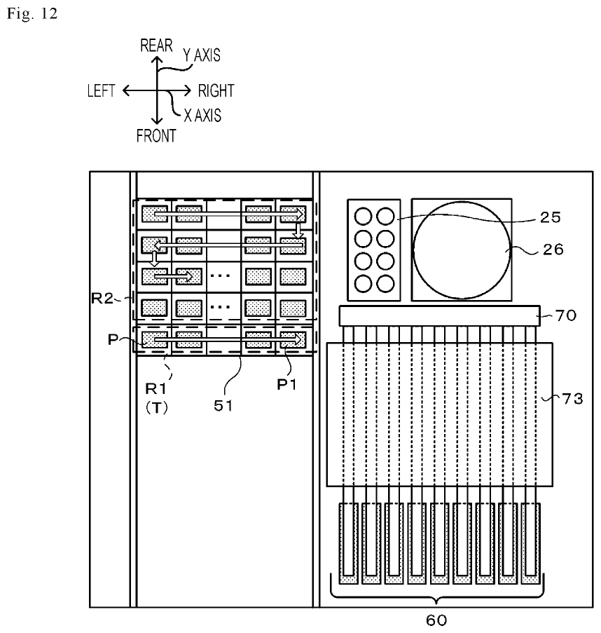

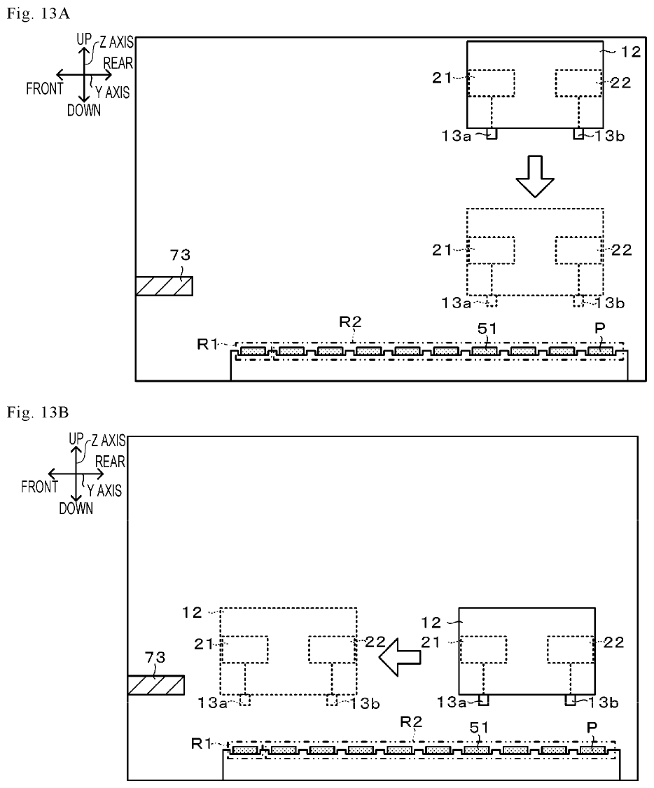

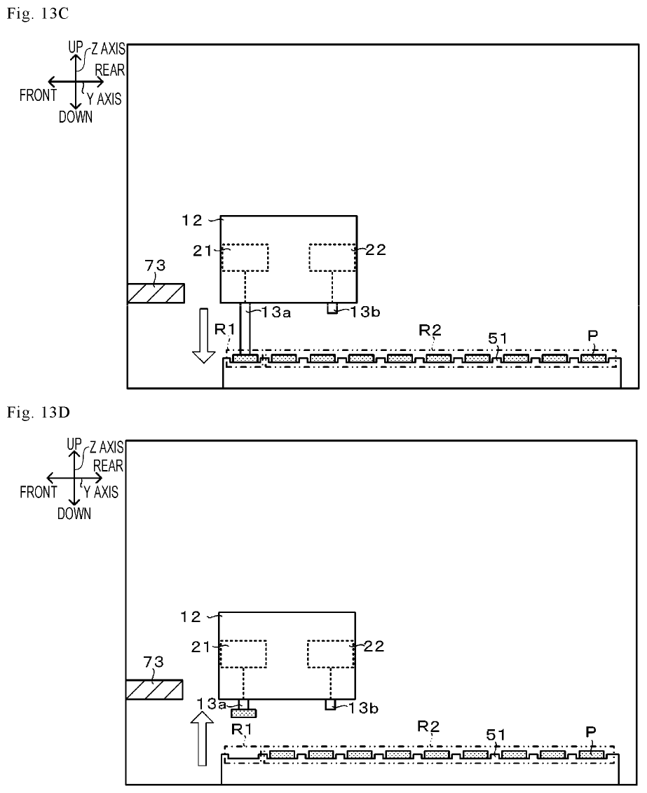

Next, a component mounting process of component mounter 10 configured in this manner will be described with reference to FIGS. 11 to 13D. FIG. 11 is a flowchart illustrating an example of a component mounting process routine. FIG. 12 is a diagram illustrating first region R1 and second region R2. FIGS. 13A to 13D are diagrams illustrating an operation of head 12 when the component mounting process is executed. The routine of the component mounting process is stored in storage 83, and is started after a production job (data in which an order of mounting components, a target mounting position of the component, the scheduled number of boards S to be manufactured, and the like are stored) is input from management device 90.

When the present routine is started, first. CPU 81 executes a process of lowering head 12 (S100). Specifically, as illustrated in FIG. 13A. CPU 81 drives and causes Zs-axis motor 31 of head lifting and lowering device 30 to lower head 12 to a lowering position. The lowering position of head 12 is a position at which head 12 is closest to component P accommodated in tray 51 within a range in which first and second suction nozzles 13a and 13b at a lifting position do not contact with tray 51 or component P accommodated in tray 51.

Next. CPU 81 executes a process of loading board S (S110). Specifically. CPU 81 causes board conveyance device 11 to convey board S conveyed from an upstream side to a predetermined position of board conveyance device 11. Then. CPU 81 controls a board fixing device (not illustrated) such that board S is fixed at the predetermined position.

Next. CPU 81 determines whether there is component P accommodated in first region R1 based on the number of components P accommodated in first region R1 in advance and the number of components P already picked up from first region R1 (S120). Here, as illustrated in FIG. 12, first region R1 is specific region T, and second region R2 is a region other than specific region T of tray 51.

When an affirmative determination is made in S120. CPU 81 executes a process of picking up component P in first region R1 with first suction nozzle 13a (S130). This process is executed as follows. That is, first, as illustrated in FIG. 13B. CPU 81 drives and controls X-axis actuator 17 and Y-axis actuator 20 of head moving device 14 such that first suction nozzle 13a moves onto component P as a pickup target in first region R1. Next, as illustrated in FIG. 13C. CPU 81 drives and controls first nozzle lifting and lowering device 21 such that first suction nozzle 13a is lowered and comes into contact with component P. Then, as illustrated in FIG. 13D. CPU 81 drives and causes solenoid valve 27 to pick up component P by acting a negative pressure on a tip of first suction nozzle 13a, and also drives and causes first nozzle lifting and lowering device 21 to lift suction nozzle 13 and pick up component P from tray 51.

Next. CPU 81 executes a process of picking up component P in the second region R2 by second suction nozzle 13b (S130). This process is executed as follows. That is, first. CPU 81 drives and controls X-axis actuator 17 and Y-axis actuator 20 of head moving device 14 such that second suction nozzle 13b moves onto component P as a pickup target in second region R2. Next. CPU 81 drives and controls second nozzle lifting and lowering device 22 such that second suction nozzle 13b is lowered and comes into contact with component P as a pickup target. Then. CPU 81 drives and controls second nozzle lifting and lowering device 22 and solenoid valve 27 such that component P as a pickup target is picked up. In first region R1 and second region R2, the component as a pickup target is determined in accordance with a predetermined pickup order (for example, an order of an arrow illustrated in FIG. 12).

On the other hand, when a negative determination is made in S120. CPU 81 executes a process of picking up component P in the second region R2 by first suction nozzle 13a and second suction nozzle 13b (S150). Specifically. CPU 81 drives and controls X-axis actuator 17 of head moving device 14. Y-axis actuator 20 of head moving device 14, first nozzle lifting and lowering device 21, second nozzle lifting and lowering device 22, and solenoid valve 27 such that components P as pickup targets in second region R2 of tray 51 are picked up by first suction nozzle 13a and second suction nozzle 13b in order.

After S140 or S150. CPU 81 executes a process of mounting component P (S160). The process of mounting component P is executed as follows. That is, first. CPU 81 drives and causes Zs-axis motor 31 of head lifting and lowering device 30 to move head 12 to a head height when mounting component P. Here, the head height when mounting component P is a position of head 12 at which a component already mounted on board S and first and second suction nozzles 13a and 13b at the lifting position do not come into contact with each other. In a case where there are the multiple such positions, the lowest position is the head height when mounting component P. Next. CPU 81 drives and controls X-axis actuator 17 and Y-axis actuator 20 of head moving device 14 such that each component P picked up by first suction nozzle 13a and second suction nozzle 13b move above part camera 26. Next. CPU 81 controls part camera 26 such that each component P is imaged by part camera 26. Next. CPU 81 determines a pickup deviation of component P with respect to first suction nozzle 13a based on the captured image, determines the pickup deviation of component P with respect to second suction nozzle 13b, and corrects a target mounting position of each component P in a direction in which the pickup deviation is to be removed. Then. X-axis actuator 17 of head moving device 14. Y-axis actuator 20 of head moving device 14, first nozzle lifting and lowering device 21, second nozzle lifting and lowering device 22, and solenoid valve 27 are driven and controlled such that component P picked up by first suction nozzle 13a and component P picked up by second suction nozzle 13b are mounted in order at the respective target mounting positions.

Next. CPU 81 executes a process of picking up a component of tape feeder 60 by first suction nozzle 13a and second suction nozzle 13b (S170). This process is executed as follows. That is, first. CPU 81 drives and causes Zs-axis motor 31 of head lifting and lowering device 30 to move head 12 to the vicinity of a component supplied by tape feeder 60 in a range in which first and second suction nozzles 13a and 13b at the lifting position do not contact with a tape or the component. Then. CPU 81 controls various members such that the component of tape feeder 60 is picked up by first suction nozzle 13a and second suction nozzle 13b.

Next. CPU 81 executes a process in the same manner as S160, and controls various members such that the components picked up from tape feeder 60 in S170 are mounted in order on board S (S180).

Next, when all the components to be mounted by the host machine are mounted on board S. CPU 81 executes a process of unloading board S (S190). Specifically. CPU 81 causes the board fixing device (not illustrated) to release the fixing of board S, and causes board conveyance device 11 to convey board S downstream.

Then. CPU 81 determines whether the scheduled number of boards S are manufactured (S200). In a case where a negative determination is made in S200. CPU 81 returns to S100 again. On the other hand, in a case where an affirmative determination is made in S200. CPU 81 ends the present routine.

Since component mounter 10 described in detail above includes head lifting and lowering device 30 that vertically moves head 12, component P accommodated in tray 51 can be picked up in a state where head 12 is lowered to the vicinity of component P accommodated in tray 51 by driving of head lifting and lowering device 30. Therefore, the amount of vertical movement of suction nozzle 13 by first nozzle lifting and lowering device 21 and second nozzle lifting and lowering device 22 can be reduced. Accordingly, when component P accommodated in tray 51 is picked up by using suction nozzle 13, a time required for picking up component P can be shortened.

In addition, in component mounter 10, in a state where head 12 is lowered by head lifting and lowering device 30, head 12 does not come into contact with cover member 73 in a case where component P in specific region T of tray 51 is picked up by using first lifting suction nozzle 13a, and comes into contact with cover member 73 in a case where component P in specific region T of tray 51 is picked up by using second lifting suction nozzle 13b, and first region R1 is specific region T. and second region R2 is a region other than the specific region T, in some cases. Therefore, even in a case where suction nozzle 13 of either first suction nozzle 13a or second suction nozzle 13b picks up component P accommodated in tray 51, head 12 can be prevented from coming into contact with cover member 73.

In the embodiment described above, component mounter 10 includes head lifting and lowering device 30. Meanwhile, head lifting and lowering device 30 need not be provided. In this case, control device 80 may execute a process in the same manner as S110 to S200 of the component mounting process routine of the embodiment described above in the component mounting process. In this case as well, even in a case where suction nozzle 13 picks up a component accommodated in tray 51, head 12 can be prevented from coming into contact with an obstacle (cover member 73).

Although in the embodiment described above, when a pickup operation is performed by second suction nozzle 13b, head 12 interferes with cover member 73, when first suction nozzle 13a performs the pickup operation, the pickup operation is performed at a lower position at which head 12 does not interfere with cover member 73. Meanwhile, regardless of whether the pickup operation is performed by first suction nozzle 13a or second suction nozzle 13b, the pickup operation may be performed at a lifting position at which head 12 is lifted to a position at which head 12 does not interfere with cover member 73. In this case. CPU 81 may compare a time required for the pickup operation when head 12 is at the lifting position with a time required for the pickup operation when head 12 is at a lowering position, and may execute the pickup operation at a head position at which the required time is shorter. The lifting position of head 12 is the lowest position among positions of head 12 at which head 12 and cover member 73 do not come into contact with each other even when component P in specific region T is picked up by second suction nozzle 13b. The pickup operation when head 12 is at the lifting position is executed as follows. That is. CPU 81 controls various members such that components P as pickup targets determined based on a pickup order are picked up in order by first suction nozzle 13a and second suction nozzle 13b, regardless of whether component P is in first region R1 or second region R2. On the other hand, the pickup operation in a case where head 12 is at the lowering position is as in the embodiment described above. Since head 12 is separated from the tray (component), in a case where head 12 is at the lifting position, a time required to vertically move first and second suction nozzles 13a and 13b by first and second nozzle lifting and lowering devices 21 and 22 is longer than a case where head 12 is at the lowering position. Meanwhile, since components P adjacent to each other can be picked up by first and second suction nozzles 13a and 13b, a time required to move head 12 in the horizontal direction is shorter than a case where head 12 is at the lower position. On the other hand, in a case where head 12 is at the lowering position, head 12 is closer to the tray (component) than a case where head 12 is at the lifting position, so that a time required to vertically move first and second suction nozzles 13a and 13b by first and second nozzle lifting and lowering devices 21 and 22 becomes shorter. Meanwhile, since component P in first region R1 and component P in second region R2, which are separated from each other, are alternately picked up, a time required to move head 12 in the horizontal direction is longer than a case where head 12 is at the upper position. Here. CPU 81 compares the required times as follows. That is, by setting a position of head 12 to the upper position, even in a case where a time required for the vertical movement of first and second lifting and lowering devices 21 and 22 becomes longer than a case where head 12 is at the lower position, if a time required for the horizontal movement of head 12 is further shortened. CPU 81 determines that the required time is shorter when head 12 is at the upper position, and executes the pickup operation of component P accommodated in tray 51 in a state where head 12 is at the upper position. Otherwise. CPU 81 determines that the required time is shorter when head 12 is at the lower position, and executes the pickup operation of component P accommodated in tray 51 in a state where head 12 is at the lower position. The required time is determined in advance based on a size of head 12 or a size of tray 51.

In the embodiment described above, component mounter 10 is described, and a method for manufacturing a board may be used. This also applies to the modification example described above.

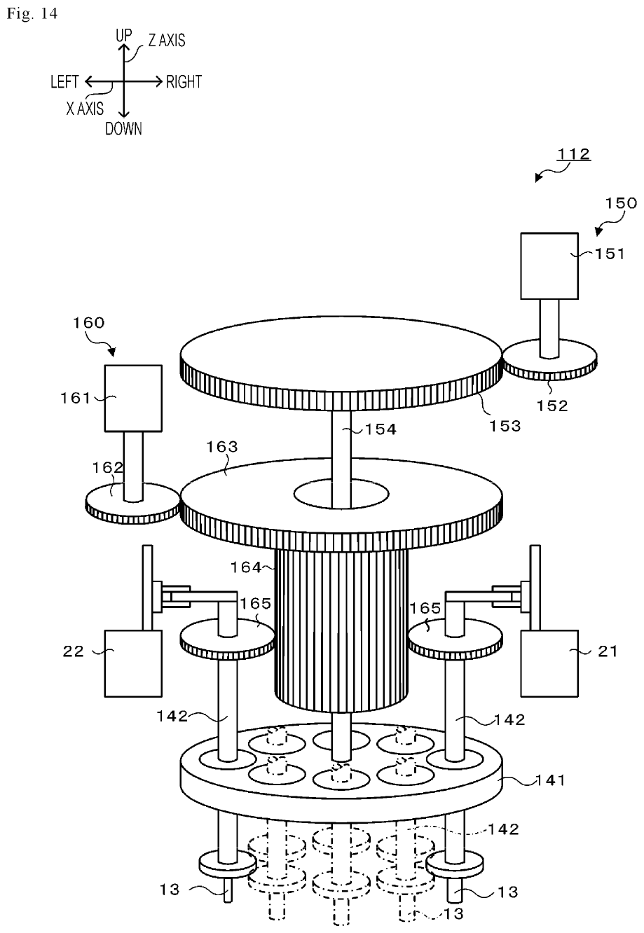

In the embodiment described above, head 12 is a two-nozzle head that holds two suction nozzles 13. Meanwhile, instead of the two-nozzle head, a head in which three or more nozzles are held to be aligned in a linear shape or a lattice shape may be adopted. Alternatively, as illustrated in FIG. 14, rotary head 112 that holds multiple (eight in FIG. 14) nozzles 13 to be arranged circumferentially may be adopted. As illustrated in FIG. 14, rotary head 112 includes head main body 141, nozzle holder 142, suction nozzle 13, first drive device 150, second drive device 160, first nozzle lifting and lowering device 21, and second nozzle lifting and lowering device 22. Head main body 141 is a disk-shaped rotating body. Multiple nozzle holders 142 are provided at predetermined intervals in a circumferential direction of head main body 141. Suction nozzle 13 is attached to a tip portion of each nozzle holder 142 in an exchangeable manner. First drive device 150 transmits power of motor 151 to head main body 141 connected to shaft 154 via gears 152 and 153, and rotates multiple nozzle holders 142 supported by head main body 141 in the circumferential direction together with multiple suction nozzles 13. Second drive device 160 transmits power of motor 161 to nozzle holder 142 via gears 162 to 165, and rotates nozzle holder 142. First nozzle lifting and lowering device 21 and second nozzle lifting and lowering device 22 are provided at two positions arranged in the X-axis direction on a revolving trajectory, and are configured to individually lift and lower nozzle holders 142 at the two positions. In FIG. 14, for convenience of description, nozzle holder 142 at a position engaged with first nozzle lifting and lowering device 21 and nozzle holder 142 at a position engaged with second nozzle lifting and lowering device 22 are indicated by solid lines, and remaining nozzle holders 142 are indicated by one-dot chain lines. In a component mounter including rotary head 112 as well, if suction nozzle 13 being vertically moved by second nozzle lifting and lowering device 22 picks up a component in a specific region of a tray, head 112 interferes with cover member 73 in some cases. Therefore, a process in the same manner as the embodiment described above can be applied.

### INDUSTRIAL APPLICABILITY

The present disclosure can be applied to a manufacturing industry of a component mounter, a component mounting system, or the like.

### REFERENCE SIGNS LIST

1: component mounting system, 10: component mounter, 10a: mounting machine main body, 10b: base, 10c: casing, 11: board conveyance device, 12: head, 13: suction nozzle, 13a: first suction nozzle, 13b: second suction nozzle, 14: head moving device, 15: X-axis guide rail, 16: X-axis slider, 17: X-axis actuator, 18: Y-axis guide rail, 19: Y-axis slider, 20: Y-axis actuator, 21: first nozzle lifting and lowering device, 22: second nozzle lifting and lowering device, 23a: first θ-axis actuator, 23b: second θ-axis actuator, 24: mark camera, 25: nozzle stocker, 26: part camera, 27: solenoid valve, 28: vacuum pump, 29: air pipe, 30: head lifting and lowering device, 31: Zs-axis motor, 32: ball screw, 33: movable body, 40: tray unit, 50: tray feeder, 51: tray, 52: magazine, 53: holding section, 54: tray storage device, 55: tray moving device, 60: tape feeder, 61: tape reel, 62: holding member, 63: main body portion, 64, 65, 66: step surface, 67: tape feeding mechanism, 68: rail, 69: connector, 70: feeder table, 71: slot, 72: connector, 73: cover member, 80: control device, 81: CPU, 82: ROM, 83: storage, 84: RAM, 90: management device, 112: rotary head, 141: head main body, 142: nozzle holder, 150: first drive device, 151, 161: motor, 152, 153, 162 to 165: gear, 154: shaft, 160: second drive device

1. A component mounter for collecting a component accommodated in a tray supplied from a tray unit and mounting the component on a board, comprising:
a head configured to hold multiple collecting members capable of collecting the component;
a first lifting and lowering device configured to vertically move a collecting member at a predetermined position of the head with respect to the head;
a second lifting and lowering device configured to vertically move a collecting member at a position different from the predetermined position of the head with respect to the head;
a head lifting and lowering device configured to vertically move the head; and
a head moving device configured to move the head in a horizontal direction together with the head lifting and lowering device.

2. The component mounter according to claim 1, further comprising:
a control device configured to cause the head moving device, the head lifting and lowering device, the first lifting and lowering device, and the second lifting and lowering device to collect a component accommodated in a first region by the collecting member that is vertically moved by the first lifting and lowering device, and to collect a component accommodated in a second region different from the first region by the collecting member that is vertically moved by the second lifting and lowering device, among components accommodated in the tray.

3. The component mounter according to claim 2, wherein
in a state where the head is lowered by the head lifting and lowering device, the head does not come into contact with an obstacle in a case where a component in a specific region of the tray is collected by using the collecting member that is vertically moved by the first lifting and lowering device, and comes into contact with the obstacle in a case where the component in the specific region of the tray is collected by using the collecting member that is vertically moved by the second lifting and lowering device,
the first region is the specific region, and
the second region is a region other than the specific region.

4. The component mounter according to claim 3, wherein
the obstacle is a cover member that covers an upper portion of a tape feeder disposed at a position adjacent to the tray in the tray unit.

5. A component mounter for collecting a component accommodated in a tray supplied from a tray unit and mounting the component on a board, comprising:
a head configured to hold multiple collecting members capable of collecting the component;
a first lifting and lowering device configured to vertically move a collecting member at a predetermined position of the head with respect to the head;
a second lifting and lowering device configured to vertically move a collecting member at a position different from the predetermined position of the head with respect to the head;
a head moving device configured to move the head in a horizontal direction; and
a control device configured to cause the head moving device, the first lifting and lowering device, and the second lifting and lowering device to collect a component accommodated in a first region by the collecting member that is vertically moved by the first lifting and lowering device, and to collect a component accommodated in a second region different from the first region by the collecting member that is vertically moved by the second lifting and lowering device, among components accommodated in the tray, wherein
the head does not come into contact with an obstacle in a case where a component in a specific region of the tray is collected by using the collecting member that is vertically moved by the first lifting and lowering device, and comes into contact with the obstacle in a case where the component in the specific region of the tray is collected by using the collecting member that is vertically moved by the second lifting and lowering device,
the first region is the specific region, and
the second region is a region other than the specific region.

6. A method for manufacturing a board in a component mounter including
a head configured to hold multiple collecting members capable of collecting a component accommodated in a tray supplied from a tray unit,
a first lifting and lowering device configured to vertically move a collecting member at a predetermined position of the head with respect to the head,
a second lifting and lowering device configured to vertically move a collecting member at a position different from the predetermined position of the head with respect to the head, and
a head moving device configured to move the head in a horizontal direction, the method comprising:
collecting a component accommodated in a first region by the collecting member that is vertically moved by the first lifting and lowering device; and
collecting a component accommodated in a second region different from the first region by the collecting member that is vertically moved by the second lifting and lowering device, among components accommodated in the tray.
